(19) United States
(12) Patent Application Publication
(10) Pub. No.: US 2009/0101880 A1
(43) Pub. Date: Apr. 23, 2009

(54) PHASE CHANGE MEMORY DEVICES AND METHODS FOR FABRICATING THE SAME

(75) Inventor: Li-Shu Tu, Taoyuan County (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARCH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC., HSINCHU (TW); WINBOND ELECTRONICS CORP., HSINCHU (TW)

(21) Appl. No.: 11/964,618

(22) Filed: Dec. 26, 2007

(30) Foreign Application Priority Data
Oct. 17, 2007 (TW) TW96138842

(51) Int. Cl. H01L 47/00; B05D 5/12

(52) U.S. Cl. 257/2; 427/58; 257/E47.001

(57) ABSTRACT

An exemplary memory device includes a first dielectric layer with a first conductive contact therein. A phase change material (PCM) is disposed on top of the first dielectric layer and provided with an insulating layer integrally on a top surface of the PCM. A first electrode is disposed over the first dielectric layer and covered a portion of the first conductive contact and the insulating layer in a first direction, contacting to the first conductive contact and a first side of the PCM. A second electrode is disposed over the first dielectric layer and covered a portion of the insulating layer in a second direction, contacting to a second side of the PCM. A second dielectric layer is disposed over the first dielectric layer to cover the first electrode, the second electrode, the insulating layer and the PCM, including a second conductive contact connected to the second electrode.

### BACKGROUND OF THE INVENTION

1. Field of the Invention

The invention relates to memory devices, and more particularly to a phase change memory (PCM) device and a method for fabricating the same.

2. Description of the Related Art

Phase change memory devices are non-volatile, highly readable, and highly programmable, and require a relatively lower driving voltage/current. Current trends in phase change memory development are to increase cell density and reduce working currents such as write currents and reset currents thereof.

Phase change material in a phase change memory device has at least two solid phases, a crystalline state and an amorphous state. Transformation between these two phases can be achieved by changing the temperature of the phase change material. The phase change material exhibits different electrical characteristics depending on its state. For example, in its amorphous state the material exhibits a higher resistivity than in the crystalline state. Such phase change material may switch between numerous electrically detectable conditions of varying resistivities within a nanosecond time scale with the input of pico joules of energy. Since phase change material permits reversible phase transformation, memory bit status can be distinguished by determining the phase of phase change material in the memory bit.

FIG. 1 is a schematic diagram showing a cross sectional view of a conventional phase change memory cell structure. As shown in FIG. 1, the phase change memory cell structure includes a silicon substrate 10 with a bottom electrode 12 made of conductive material such as Al or W thereon. A dielectric layer 14 is formed over the bottom electrode 12 and a heating electrode 16 is formed in a portion of the dielectric layer 14. Moreover, a patterned phase change material layer 20 is stacked over the dielectric layer 14. The patterned phase change material layer 20 is formed within a dielectric layer 18 which is formed over the dielectric layer 14 and a bottom surface of the phase change material layer 20, partially contacting the heating electrode 16. A dielectric layer 24 is formed over the dielectric layer 18 and a top electrode 22 is formed over and in the dielectric layer 24. The top electrode 22 partially covers the dielectric layer 24 and portions thereof protrude downward through the dielectric layer 24, thereby contacting the phase change material layer 20 thereunder.

During memory cell operation, a large current is generated by the heating electrode 16 and flows therethrough, thus heating up an interface between the phase change material layer pattern 20 and the heating electrode 16 and thereby transforming a portion (not shown) of the phase change material layer 20 into either the amorphous state or the crystalline state depending on the length of time and amount of current that flows through the heating electrode 16.

Currently, to enhance applications of phase change memory devices, size of the memory cells of the phase change memory devices is being required to be further reduced. With size reduction of the memory cell, however, it also means working current of the memory cells should also be reduced while increasing memory cell density.

One problem found with conventional phase change memory cell structure as shown in FIG. 1, is that the amount of write current and reset current required to successfully change the phase state of the phase change material during cell operation is relatively large. One solution to reduce write current and reset current and to successfully turn on the phase change reaction of the memory cells, is to reduce the contact surface between the heating electrode 16 and the phase change material layer 20, such as through reducing a diameter D₀ of the heating electrode 16, thereby maintaining or increasing a current density at the interface.

Reduction of the diameter D₀ of the heating electrode 16, however, is limited by current photolithography process ability, thereby limiting size reduction of the heating electrode 16 and ability to decrease working currents such as write current and reset current.

### BRIEF SUMMARY OF THE INVENTION

Phase change memory devices and methods for manufacturing the same are provided to thereby solve the aforementioned challenges and improve conventional phase change memory devices.

An exemplary embodiment of a phase change memory device comprises a first dielectric layer with a first conductive contact formed therein. A phase change material is disposed on top of the first dielectric layer and provided with an insulating layer integrally formed on a top surface of the phase change material. A first electrode is disposed over the first dielectric layer and covered a portion of the first conductive contact and the insulating layer in a first direction, wherein the first electrode directly contacts to the first conductive contact and a first side of the phase change material. A second electrode is disposed over the first dielectric layer and covered a portion of the insulating layer in a second direction, wherein the second electrode directly contacts to a second side of the phase change material. A second dielectric layer is disposed over the first dielectric layer to cover the first electrode, the second electrode, the insulating layer and the phase change material, wherein the second dielectric layer comprises a second conductive contact connected to the second electrode.

An exemplary embodiment of a method for manufacturing a phase change memory device comprises providing a first dielectric layer with a first conductive contact formed therein and a stacked structure formed thereon, wherein the stacked structure comprises a phase change material layer and an insulating layer sequentially formed over the first dielectric layer. A conductive strap is formed on the first dielectric layer to cover a portion of the stack structure and the conductive contact, wherein the conductive strap is directly in contact with at least two sides of the phase change material layer and the first conductive contact. The conductive strap formed on a top surface of the stacked structure is partially removed to form a first conductive electrode and a second conductive electrode electrically insulated from the first conductive electrode, wherein the first conductive electrode and the second conductive electrode are in contact with a respective one of the two sides of the phase change material layer, and the first conductive electrode is in contact with the first conductive contact. A second dielectric layer with a second conductive contact therein is formed over the first dielectric layer, wherein the second conductive contact is in contact with the second conductive electrode.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is cross section of a conventional phase change memory cell structure;

FIGS. 2, 5, 8, 12 and 16 are schematic diagrams respectively showing a top view in various fabrication steps of a phase change memory device according to an embodiment of the invention;

FIG. 3 is a schematic diagram showing a cross section taken along line 3-3 in FIG. 2;

FIG. 4 is a schematic diagram showing a cross section taken along line 4-4 in FIG. 2;

FIG. 6 is a schematic diagram showing a cross section taken along line 6-6 in FIG. 5;

FIG. 7 is a schematic diagram showing a cross section taken along line 7-7 in FIG. 5;

FIG. 9 is a schematic diagram showing a cross section taken along line 9-9 in FIG. 8;

FIG. 10 is a schematic diagram showing a cross section taken along line 10-10 in FIG. 8;

FIG. 11 is a schematic diagram showing a cross section taken along line 11-11 in FIG. 8;

FIG. 13 is a schematic diagram showing a cross section taken along line 13-13 in FIG. 12;

FIG. 14 is a schematic diagram showing a cross section taken along line 14-14 in FIG. 12;

FIG. 15 is a schematic diagram showing a cross section taken along line 15-15 in FIG. 12;

FIG. 17 is a schematic diagram showing a cross section taken along line 17-17 in FIG. 16;

FIG. 18 is a schematic diagram showing a cross section taken along line 18-18 in FIG. 16;

FIG. 19 is a schematic diagram showing a cross section taken along line 19-19 in FIG. 16; and

FIG. 20 is a schematic diagram showing a cross section taken along line 20-20 in FIG. 16.

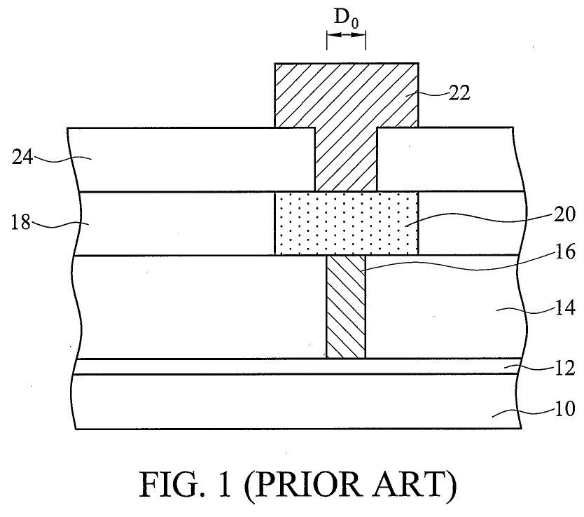

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

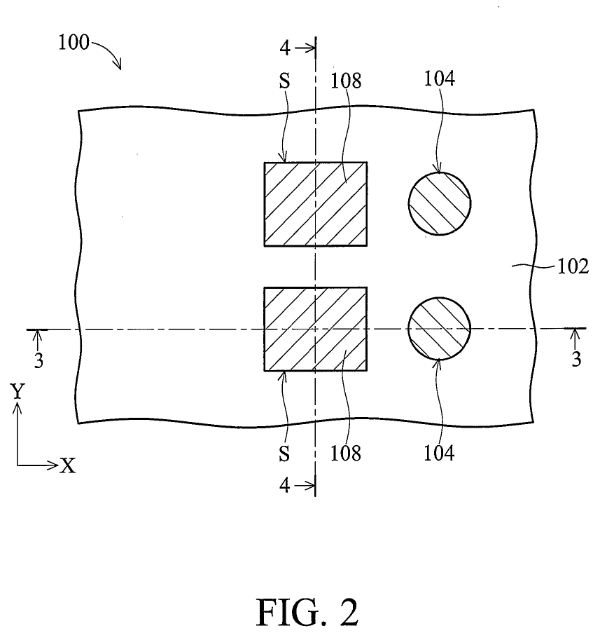

Embodiments of phase change memory devices and methods for fabricating the same are described as below incorporating FIGS. 2-20. FIGS. 2, 5, 8, 12 and 16 are schematic diagrams respectively showing a top view of various fabrication steps of a phase change memory device according to an exemplary embodiment of the invention, with the remaining schematic diagrams respectively showing a cross section taken along predetermined lines of top views.

In the embodiment, the schematic diagrams only illustrate manufacturing of a plurality of phase change memory cells in a phase change memory device. Note that the phase change memory device in the embodiment further comprises other conductive components (e.g. interconnection plugs or interconnecting lines) for electrically connecting the phase change memory cell with an active device (e.g. transistor or diode) and a conductive line. These conductive components and the active devices, however, are not shown in the schematic diagrams, for simplicity.

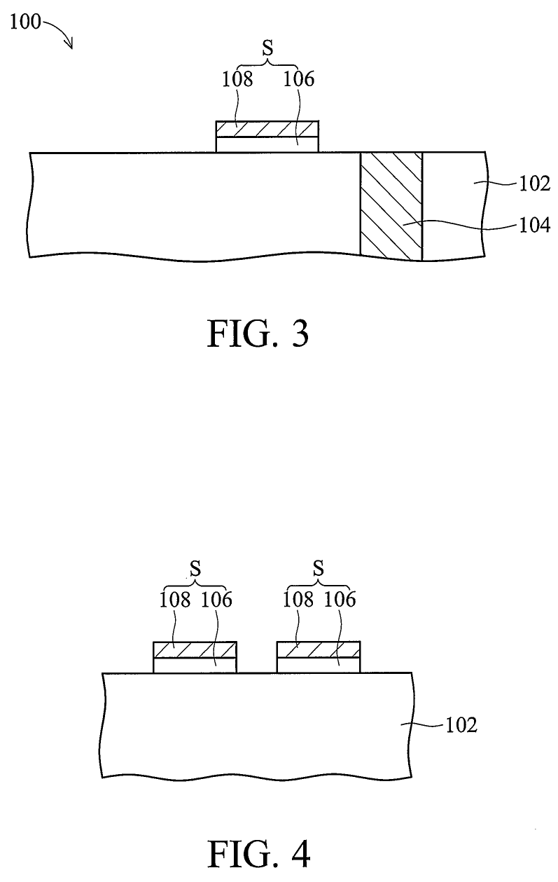

Referring to FIG. 2, a substantially fabricated semiconductor structure 100 is first provided, including two conductive contacts 104 disposed in a dielectric layer 102 and two stacked structure S formed over the dielectric layer 102. As shown in FIG. 2, the conductive contacts 104 and stacked structures S are electrically isolated and aligned from each other along a Y direction, wherein each of the stacked structures S includes a phase change material layer 106 and an insulating layer 108 (see FIG. 3) sequentially stacked over the dielectric layer 102. Herein, fabrication sequence of the stacked structures S and the conductive contacts 104 can be interchanged according to fabrication processes demands. That is, the conductive contacts 104 can be first formed in the dielectric layer 102 and the stacked structures S are then formed over the dielectric layer 102, or the stacked structures S are first formed over the dielectric layer 102 and the conductive contacts 104 are then formed in the dielectric layer 102.

FIGS. 3 and 4 are schematic diagrams respectively showing a cross section along lines 3-3 and 4-4 in FIG. 2. FIG. 3 substantially illustrates disposition of a stacked structure S and a conductive contact 104 and FIG. 4 substantially illustrates dispositions of two stacked structures S. The phase change material layer 106 of the stacked structures S may comprise chalcogenide materials such as Ge—Sb—Te trinary chalcogenide compound or Te—Sb binary chalcogenide compound and has a thickness of about 200-500 Å. The insulating layer 108 formed over the phase change material layer 106 may be a silicon nitride layer having a thickness of about 200-500 Å. The dielectric layer 102 may comprise borophosphosilicate glass (BPSG), silicon oxide, spin-on glass (SOG) or silicon nitride. The conductive contacts 104 may comprise conductive materials such as tungsten or doped polysilicon. Herein, patterning of the conductive contacts 104 and the stacked structure S can be achieved by conventional contact processing, film deposition, photolithography and etching processes and are not described in detail here, for brevity.

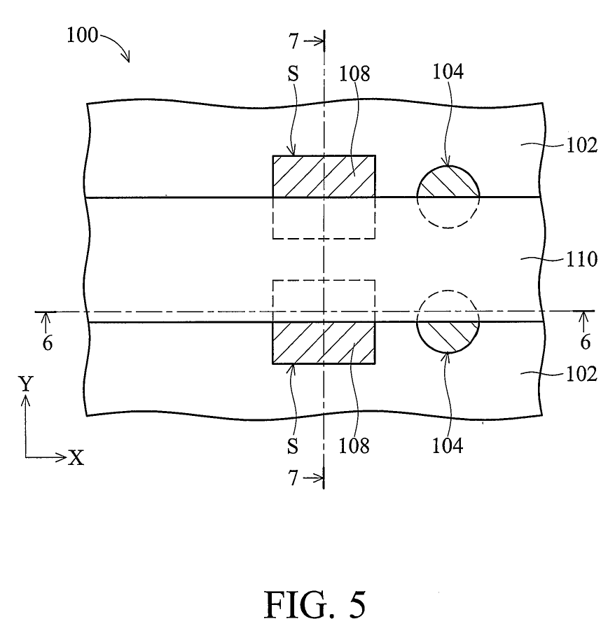

In FIG. 5, a layer of dielectric material is conformably formed over the structure illustrated in FIG. 2 to cover the dielectric layer 102, the stacked structures S and the conductive contacts 104. The layer of dielectric material is then patterned by sequential photolithography and etching processes (both not shown) to form a patterned dielectric layer 110. Herein, the dielectric layer 110 is illustrated as a dielectric layer formed over portions of the dielectric layer 102 and extending along an X-direction as shown in FIG. 5. The dielectric layer 110 partially covers each of the stacked structures S and the conductive contacts 104. Herein, the dielectric layer 110 may comprise borophosphosilicate glass (BPSG), silicon oxide, spin-on glass (SOG) or silicon nitride and has a thickness of about 2000-3000 Å. The dielectric layer 110 may comprise dielectric materials different from that of the dielectric layer 102 to provide suitable selective etching performances during patterning thereof.

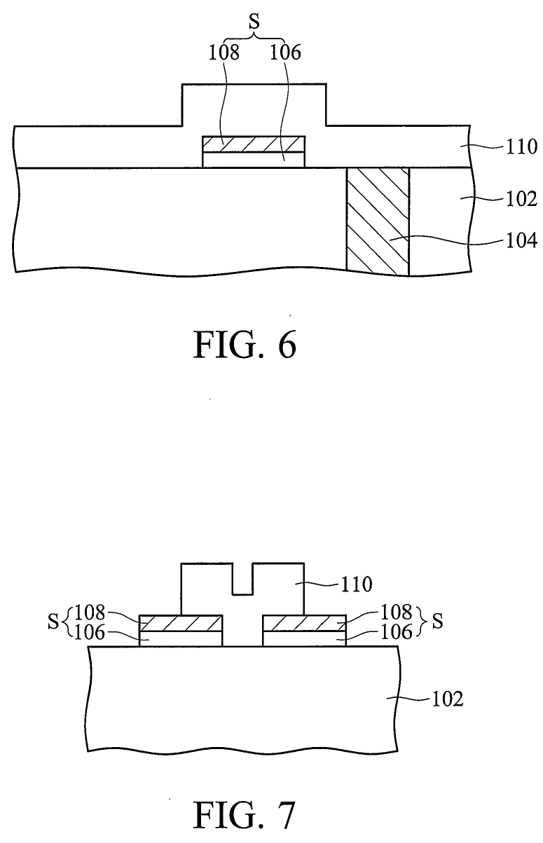

FIGS. 6 and 7 are schematic diagrams respectively showing a cross section along lines 6-6 and 7-7 in FIG. 5. Herein, FIG. 6 substantially illustrates the dielectric layer 110 which is conformably formed over the dielectric layer 102, the stacked structure S and the conductive contact 104 and FIG. 7 substantially illustrates dispositions of the dielectric layer 110 conformably formed between two adjacent stacked structures S. As shown in FIG. 7, the dielectric layer 110 merely covers portions of each of the stacked structures S and partially exposes the stack structures S.

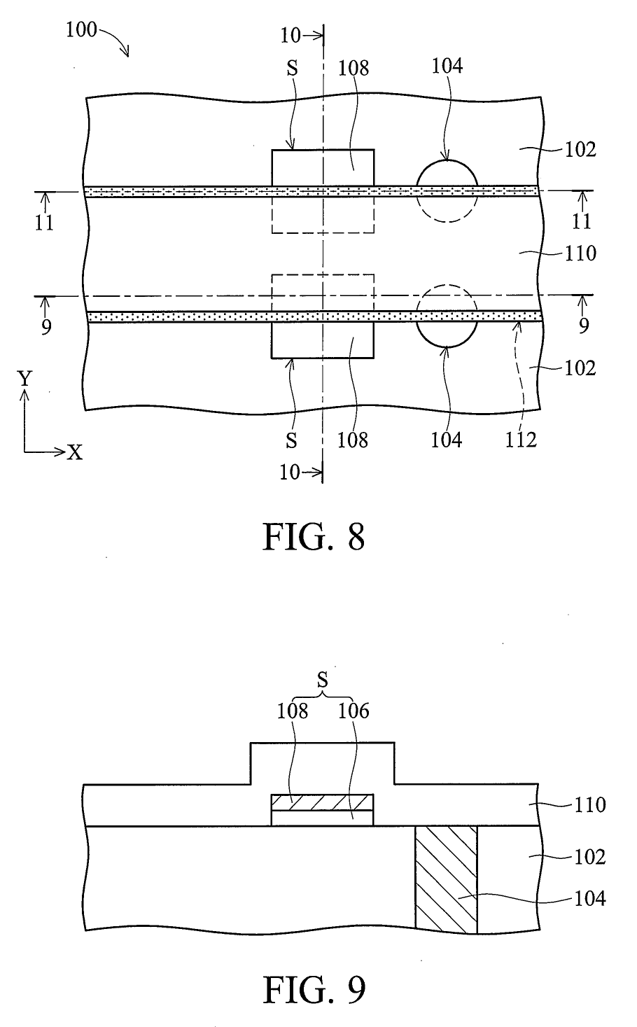

In FIG. 8, a layer of conductive material (not shown) is then deposited over the structure illustrated in FIG. 5 and an etching process (not shown) is next performed to etch back the layer of conductive material (not shown), thereby leaving a conductive spacer 112 on opposite sidewalls of the dielectric layer 110 at a Y-direction as shown in FIG. 8. The conductive spacers 112 respectively extend along an X-direction as shown in FIG. 8 and partially covers top surfaces of the dielectric layer 102, the conductive contact 104 and the stacked structures S not covered by the dielectric layer 110. Each of the conductive spacers 112 may comprise conductive materials such as Ti or TiN. Deposition for forming the conductive spacers 112 can be, for example, sputtering or chemical vapor deposition.

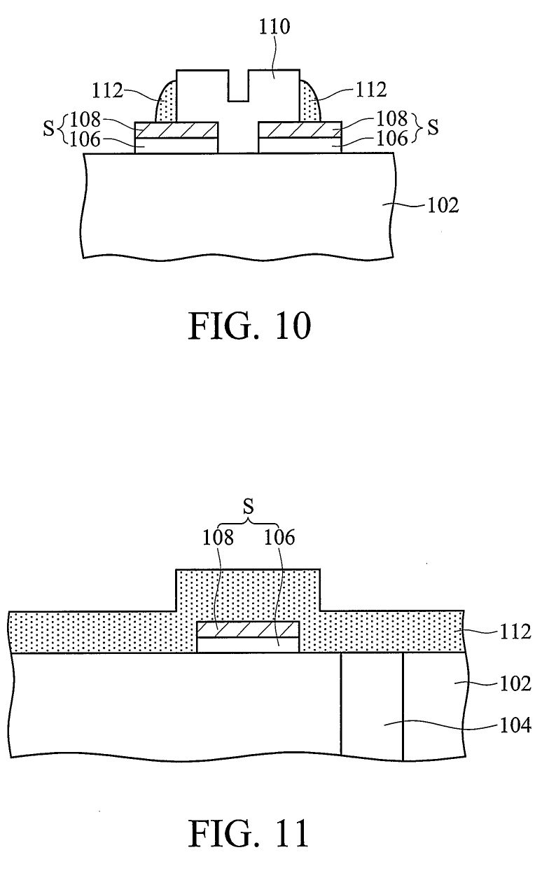

FIGS. 9-11 are schematic diagrams respectively showing a cross section along lines 9-9, 10-10 and 11-11 in FIG. 8. Herein, as shown in FIG. 9, since the conductive spacer is not formed over the top surface of the dielectric layer 110 and the dielectric layer 110 is merely conformably formed over the dielectric layer 102, only the stacked structure S and the conductive contact 104 are illustrated. In FIG. 10, the conductive spacer formed between two adjacent stacked structures S are substantially illustrated. As shown in FIG. 10, the conductive spacers 112 are respectively and partially covering a top surface of each of the stacked structure S and is substantially lower than a top surface of the dielectric layer 110, having a fan-shaped cross section. In FIG. 11, relative dispositions between one of the conductive spacers 112 and stacked structure S, the dielectric layer 102 and the conductive contacts 104 are illustrated. Herein, the conductive spacer 112 is conformably disposed over a top surface of the above components and is in contact with opposite sidewalls of the insulating layer 108 and the phase change material layer 106 of the stacked structure S.

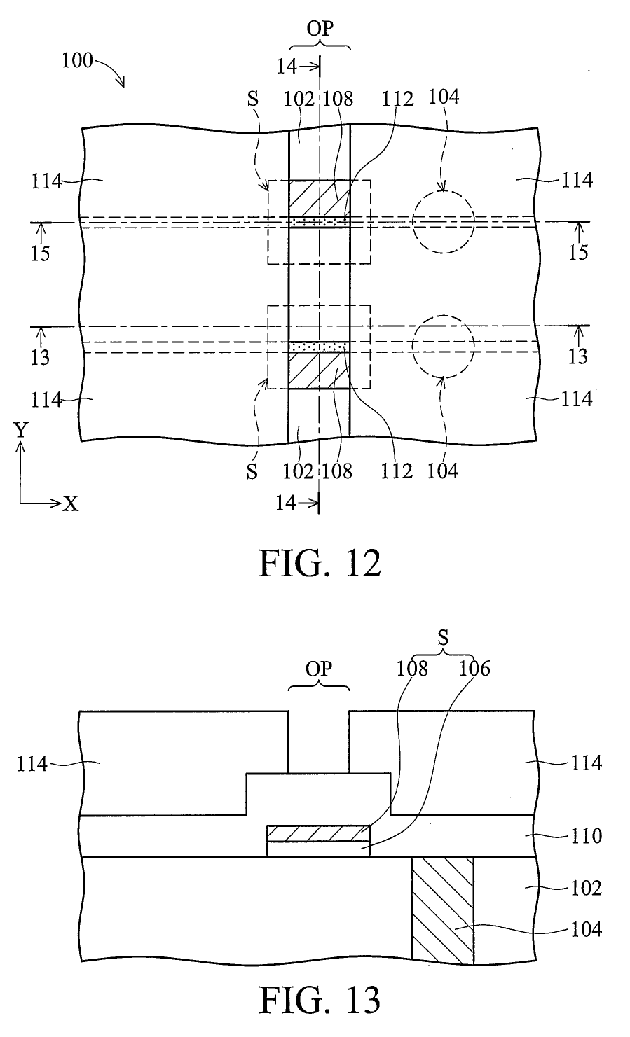

In FIG. 12, a sacrificial layer 114 is then formed over the structure illustrated in FIG. 8 to provide a planar surface. The sacrificial layer 114 is then patterned by sequential photolithography and etching processes (both not shown), thereby forming an opening OP extending along a Y direction as shown in FIG. 12. The opening OP partially exposes the dielectric layer 110, the conductive spacer 112 and the insulating layer 108 disposed over the central portion of each of the stacked structures S and the dielectric layer 102 adjacent thereto. The sacrificial layer 114 can be, for example, a photoresist (PR) layer such as a positive-type photoresist layer or a negative-type photoresist layer.

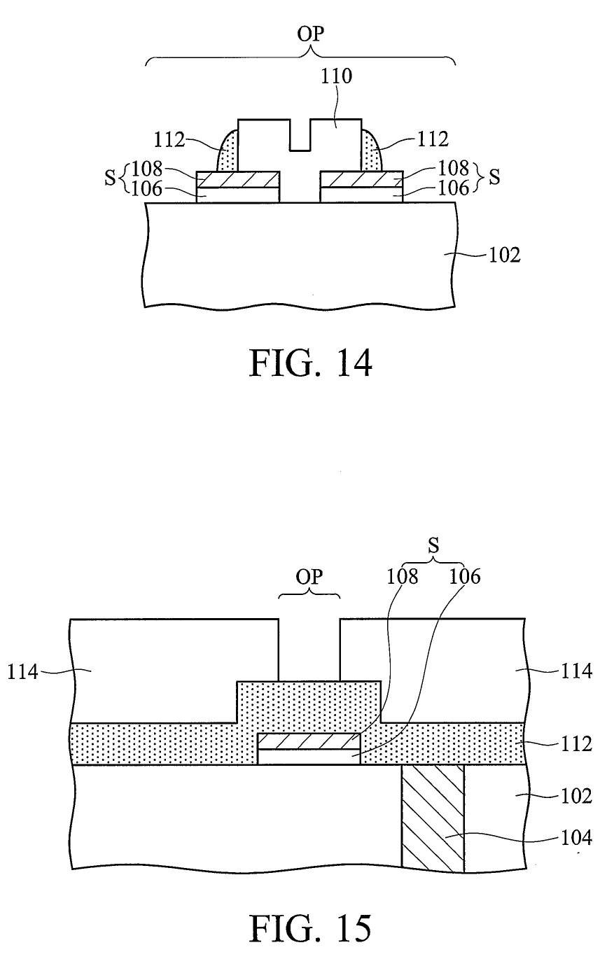

FIGS. 13-15 are schematic diagrams respectively showing a cross section along lines 13-13, 14-14 and 15-15 in FIG. 12. In FIG. 13, the opening OP substantially exposes the dielectric layer 110 over the central portion of the stacked structure S. FIG. 14 substantially illustrates disposition of the conductive spacer 112 on opposite sidewalls of the dielectric layer 110 between two stacked structures S which have a configuration similar with that illustrated in FIG. 10. In FIG. 15, the sacrificial layer 114, formed over the conductive spacer 112 and the stacked structures S, having the opening OP at a central portion of the conductive spacer 112, is illustrated.

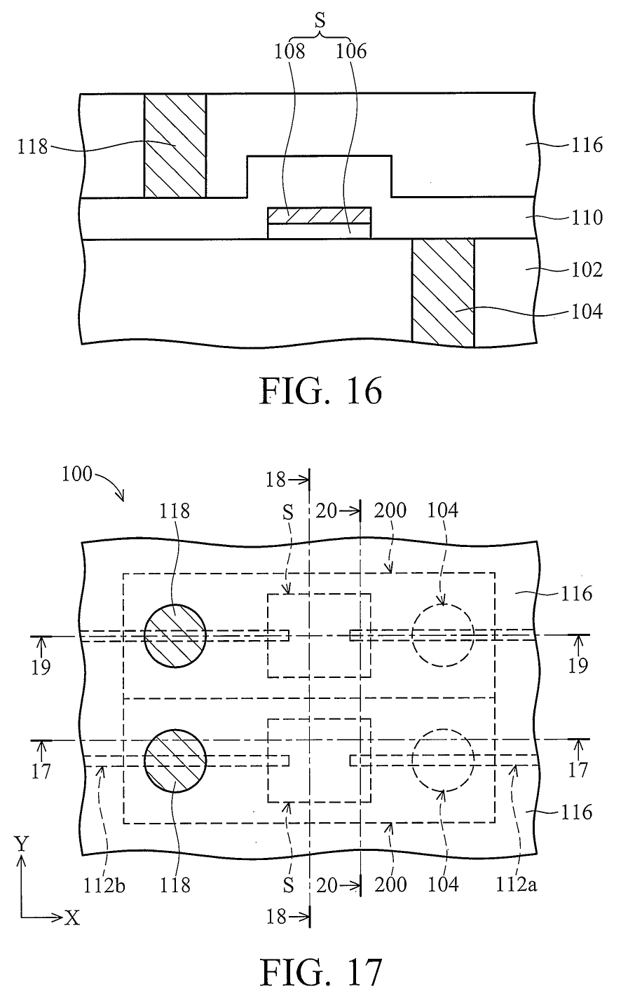

In FIG. 16, an etching process (not shown) is then performed to the structure illustrated in FIG. 12, using the sacrificial layer 114 as an etching mask, thereby removing the portion of the conductive spacer 112 exposed by the opening OP and leaving the conductive spacers 112a and 112b which have been cut at both sides of the opening OP. Next, the sacrificial layer 114 is removed and a dielectric layer 116 is then blanketly formed to planar the surface of the structure, covering the dielectric layer 110, the conductive spacers 112a and 112b, the dielectric layer 102 and the stacked structures S. Next, a plurality of conductive contacts 118 are formed in the dielectric layer 116, respectively contacting one of the conductive spacers 112b. Herein, the conductive contacts 118 are electrically isolated from each other and are arranged substantially as an array aligning to a Y direction in FIG. 16. The dielectric layer 116 may include materials such as spin-on glass (SOG) and can be formed by a spin-on method. The conductive contacts 118 may include conductive materials such as tungsten or doped polysilicon and are formed by conventional contact fabrication processes.

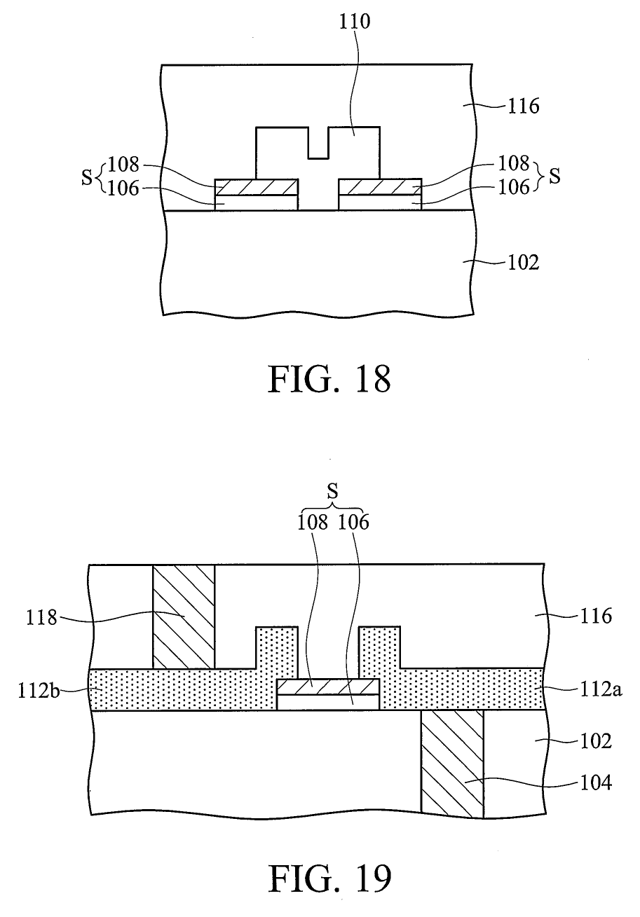

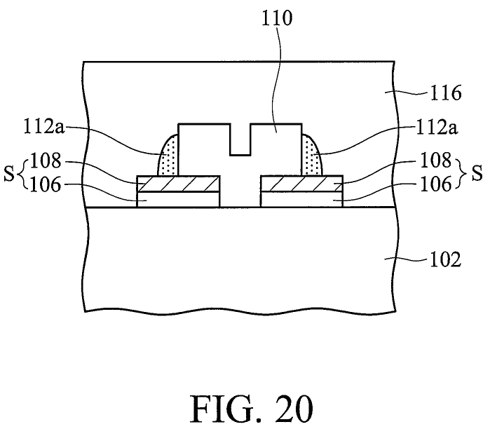

FIGS. 17-20 are schematic diagrams respectively showing a cross section along lines 17-17, 18-18, 19-19, and 20-20 in FIG. 16. In FIG. 17, the dielectric layer 116 covers the dielectric layer 110 and the conductive contact 118 is formed and embedded in the dielectric layer 118. FIG. 18 substantially illustrates the dielectric layer 116 covering the dielectric layer 110, the dielectric layer 102 and the stacked structure S. In FIG. 19, the cut conductive spacers 112a and 112b and the dielectric layer 116 covered thereon are illustrated. Herein, the conductive spacer 112a covers the conductive contact 104, and the conductive spacer 112b contacts with the conductive contact 118 embedded in the dielectric layer 116. These conductive spacers 112a and 112b respectively contacts the phase change material layer 106 of the stacked structure S from a sidewall thereof and partially covers the insulating layer 108 and most of the top surface thereof. In FIG. 20, a cross section similar with that in FIG. 18 is illustrated. Herein, the conductive spacers 112a and 112b are formed with similar cross sections and dispositions as that shown in FIG. 18.

According to the top view shown in FIG. 16 and the cross sections shown in FIGS. 17-20, the region 200 shown in FIG. 16 is a region for disposing a phase change memory device of an exemplary embodiment, wherein the phase change memory device includes a first dielectric layer (e.g. the dielectric layer 102) formed with a first conductive contact (e.g. the conductive contact 104) formed therein. A phase change material layer (e.g. the phase change material layer 106) formed over the first dielectric layer. An insulating layer (e.g. the insulating layer 108) disposed over the phase change material layer. A first electrode (e.g. the conductive spacer 112a) disposed over the first dielectric layer, wherein the first electrode is formed along a first direction in parallel with a top surface of the first dielectric layer to partially cover a first sidewall of the insulating layer, the phase change material layer, and the first conductive contact. A second electrode (e.g. the conductive spacer 112b) is disposed over the first dielectric layer, wherein the second electrode is formed along a second direction in parallel with a top surface of the first dielectric layer to partially cover a second sidewall of the insulating layer and the phase change material layer, the first and second sidewalls are opposite, and the first and second electrodes are electrically isolated from each other. A second dielectric layer (e.g. the dielectric layer 116) is disposed over the first dielectric layer to cover the first electrode, the second electrode, the insulating layer and the phase change material layer, wherein the second dielectric layer is formed with a second conductive contact (e.g. the conductive contact 118) connecting the second electrode.

According to the aforementioned illustrations and description, those with ordinary skill in the art should understand that disposition of active devices (e.g. transistors or diodes) and passive elements (e.g. conductive lines) underlying the dielectric layer 102 and/or overlying the dielectric layer 116 can be achieved to electrically connect the above conductive contacts 104 and 118 to allow operations of the above phase change memory device. The conductive contacts 104 and 118 may function as a bottom electrode and a top electrode and one of the conductive spacers 112a and 112b may function as a heating electrode to thereby heat the phase change material layer 106. Since the phase change material layer 116 in the embodiment of the invention contacts the conductive spacers 112a and 112b merely by a sidewall thereof and the conductive spacers 112a and 112b are formed with a fan-shaped cross section, the conductive spacers 112a and 112b merely contact a part of the phase change material layer 106. Therefore, through adjusting thicknesses of the phase change material layer 106 and the material for forming the conductive spacers 112a and 112b, a contact area between the phase change material layer and the heating electrode can be thus reduced, thereby further reducing working current of the phase change memory device. Limitations with conventional photolithography processes for reduction of the contact area between the phase change material layer and the heating electrode are mitigated. The method for fabricating the phase change memory device according to embodiments of the invention is thus suitable for fabricating a phase change memory device with reduced cell size and working current.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A memory device, comprising:
a first dielectric layer with a first conductive contact formed therein;
a phase change material disposed on top of the first dielectric layer and provided with an insulating layer integrally formed on a top surface of the phase change material;
a first electrode disposed over the first dielectric layer and covered a portion of the first conductive contact and the insulating layer in a first direction, wherein the first electrode directly contacts to the first conductive contact and a first side of the phase change material;
a second electrode disposed over the first dielectric layer and covered a portion of the insulating layer in a second direction, wherein the second electrode directly contacts to a second side of the phase change material; and
a second dielectric layer disposed over the first dielectric layer to cover the first electrode, the second electrode, the insulating layer and the phase change material, wherein the second dielectric layer comprises a second conductive contact connected to the second electrode.

2. The memory device as claimed in claim 1, wherein the first and second electrodes are electrically insulated to each other.

3. The memory as claimed in claim 2, wherein the phase change material is free of contact with the first conductive contact.

4. The memory device as claimed in claim 1, wherein the first electrode and the second electrode are made of a material selected from the group consisting of TiN and Ti.

5. The memory device as claimed in claim 3, wherein the first direction and second direction are opposite to each other and are located on two opposed sides of the phase change material.

6. The memory device as claimed in claim 5, wherein the first electrode is further formed over the insulating layer adjacent to a first sidewall of the phase change material, and the second electrode is further formed over the insulating layer adjacent to a second sidewall of the phase change material.

7. The memory device as claimed in claim 1, wherein the phase change material comprises chalcogenide materials.

8. The memory device as claimed in claim 6, wherein the first conductive contact serves as a bottom electrode.

9. The memory device as claimed in claim 6, wherein the second conductive contact serves as a top electrode.

10. The memory device as claimed in claim 6, wherein one of the first and second electrodes is a heating electrode.

11. The memory device as claimed in claim 1, wherein the first conductive contact and second conductive contact are made of a material selected from the group consisting of tungsten and doped polysilicon.

12. A method for fabricating a memory device, comprising:
providing a first dielectric layer with a first conductive contact formed therein and a stacked structure formed thereon, wherein the stacked structure comprises a phase change material layer and an insulating layer sequentially formed over the first dielectric layer;
forming a conductive strap on the first dielectric layer to cover a portion of the stack structure and the conductive contact, wherein the conductive strap is directly in contact with at least two sides of the phase change material layer and the first conductive contact;
partially removing the conductive strap formed on a top surface of the stacked structure to form a first conductive electrode and a second conductive electrode electrically insulated from the first conductive electrode, wherein the first conductive electrode and the second conductive electrode are in contact with a respective one of the two sides of the phase change material layer, and the first conductive electrode is in contact with the first conductive contact; and
forming a second dielectric layer with a second conductive contact therein over the first dielectric layer, wherein the second conductive contact is in contact with the second conductive electrode.

13. The method as claimed in claim 12, wherein the stack structure is formed not in contact with the first conductive contact.

14. The method as claimed in claim 13, wherein the step of partially removing the conductive strap comprises:
forming a sacrificial layer on the first dielectric layer to cover the conductive strap, the stacked structure and the first conductive contact;
defining an opening in the sacrificial layer to partially expose the conductive strap and to correspond to the top surface of the stack structure;
removing the exposed portion of the conductive strap; and
removing the sacrificial layer.

15. The method as claimed in claim 14, wherein the sacrificial layer is a photoresist layer.

16. The method as claimed in claim 13, wherein one of the first and second conductive electrodes serves as a heating electrode to heat the phase change material layer.

17. The method as claimed in claim 12, wherein the phase change material layer comprises chalcogenide materials.
